(19) United States
(12) Patent Application Publication
(10) Pub. No.: US 2012/0051021 A1
(43) Pub. Date: Mar. 1, 2012

(54) OUTPUT DEVICE AND OPERATION UNIT COVER

(75) Inventors: Seiji Ohsawa, Kanagawa (JP); Toshihide Ooba, Kanagawa (JP); Cheng Wee Jian, (US); Ooi Koh Hwa, (US)

(73) Assignee: Sony Corporation, Tokyo (JP)

(21) Appl. No.: 13/212,436

(22) Filed: Aug. 18, 2011

(30) Foreign Application Priority Data
Aug. 26, 2010 (JP) P2010-189538

(51) Int. Cl. H05K 7/02

(52) U.S. Cl. 361/807

(57) ABSTRACT

An output device which houses a portable device in an internal space and which outputs at least audio or images outputted from the housed portable device to the outside, includes: a case body including a housing portion housing the portable device; a lid body to be locked to the case body, closing the housing portion in a locked state with respect to the case body and opening the housing portion in a lock release state with respect to the case body as well as a window portion is formed; and an operation unit cover made of transparent or semitransparent rubber materials and attached to the lid body in a state of closing the window portion.

### FIELD

The present disclosure relates to a technical field concerning an output device and an operation unit cover. In particular, the present disclosure relates to a technical field in which plural dots are provided on the operation unit cover made of rubber materials to thereby improve visibility and user-friendliness in a portable device.

### BACKGROUND

There exists an output device which houses a portable device such as a music reproduction device and an image reproduction device in an internal space and which outputs audio and images outputted from the housed portable device to the outside.

As one of the above output devices, there is one in which a lid body can be opened and closed with respect to a case body, a portable device is mounted in the internal space with the lid body in an opened state and the portable device is stored and held in the internal space by connecting the lid body to the case body for sealing the portable device (For example, refer to JP-A-2007-313020 (Patent Document 1).

In the output device described in Patent Document 1, for example, a speaker unit for outputting audio outputted from the portable device to the outside is provided at the case body. A window portion is formed in the lid body and a transparent operation unit cover having flexibility is attached so as to cover the window portion.

In a state in which the lid body is connected to the case body, the lid body is locked with respect to the case body due to buckles pivotally supported at the case body, as a result, the internal space is sealed for securing the waterproof property. In the state in which the lid body is locked with respect to the case body and the portable device is housed in the internal space, the operation unit cover is pressed onto the portable device and the portable device is held, therefore, unnecessary movement of the portable device in the internal space is prevented.

When a user performs operation of an operation unit of the portable device with the operation unit cover from the outer surface side, for example, audio outputted from the portable device can be outputted to the outside.

### SUMMARY

However, both surfaces of the operation unit cover are formed in a planar shape in the output device described in Patent Document 1, therefore, it is likely that air enters part of a contact surface of the operation unit cover with respect to the portable device to generate air bubbles or that the operation unit cover is stuck to a display surface of the portable device to generate watermarks in the state in which the portable device is held by the operation unit cover.

When a user confirms the portable device by sight through the operation unit cover, these air bubbles or watermarks may impair visibility of a display surface, the operation unit and so on as well as may reduce user-friendliness for the user.

When the operation unit cover is stuck to the portable device, the portable device is lifted up while being stuck to the operation unit cover at the time of opening the lid body, which may affect open/close operation of the lid body or may damage the output device or the portable device due to falling of the portable device stuck to the cover.

In view of the above, it is desirable to provide an output device and an operation unit cover which can improve visibility and user-friendliness with respect to the portable device.

An embodiment of the present disclosure is directed to an output device which houses a portable device in an internal space and which outputs at least audio or images outputted from the housed portable device to the outside including a case body including a housing portion housing the portable device, a lid body to be locked to the case body, closing the housing portion in a locked state with respect to the case body and opening the housing portion in a lock release state with respect to the case body as well as a window portion is formed, and an operation unit cover made of transparent or semitransparent rubber materials and attached to the lid body in a state of closing the window portion, in which the housing portion includes a frame-shaped housing rib, the housing portion includes a housing recess surrounded by the housing rib and a bottom surface is a placing surface for the portable device, the operation unit cover is fitted onto the housing rib in the locked state to close the housing recess, the operation unit cover is provided with a front surface portion covering the housing recess in the locked state and a circumferential surface portion rising from an outer circumferential edge of the front surface portion and covering an outer peripheral surface of the housing rib in the locked state from the outside, and plural dots protruding on the placing surface side are provided at least part of a surface facing the placing surface in the locked state of the front surface portion. A pitch between the plural dots may be set to be equal to or higher than 0.5 mm and equal to or lower than 1.5 mm, and a height of the plural dots in the protruding direction on the placing surface side may be set to be equal to or higher than 0.01 mm and less than 0.05 mm.

Therefore, respective tips or respective tip portions of plural dots on the operation unit cover touch the portable device in the locked state of the output device.

In the above output device, it is preferable that an outer surface of the dots is formed to be a curved surface.

As the outer surface of the dots is formed to be the curved surface, the dots touch the portable device at point contact or in a state close to point contact.

In the above output device, it is preferable that an outer surface of the dots is formed to be a spherical surface.

As the outer surface of the dots is formed to be the spherical surface, the dots touch the portable device at point contact or in a state close to point contact.

In the above output device, it is preferable that the front surface portion of the operation unit cover includes a holding surface portion facing the placing surface of the housing recess to hold the portable device and two inclined surface units respectively continuing from both ends of the holding surface portion, in which the distance to the placing surface is increased as drawing away from the holding surface portion, and the plural dots are provided on the holding surface portion.

As the plural dots are provided on the holding surface portion, the dots are provided at minimum necessary positions.

Another embodiment of the present disclosure is directed to an operation unit cover used for an output device which houses a portable device in an internal space, which outputs at least audio or images outputted from the housed portable device to the outside and which includes a case body having a housing portion including a housing recess surrounded by a frame-shaped housing rib and a bottom surface of which is a placing surface for the portable device to house the portable device, and a lid body to be locked to the case body, closing the housing portion in a locked state with respect to the case body and opening the housing portion in a lock release state with respect to the case body as well as a window portion is formed, in which the operation unit cover is made of transparent or semitransparent rubber materials and attached to the lid body in a state of closing the window portion and closes the housing recess by being fitted onto the housing rib in the locked state, a front surface portion covering the housing recess in the locked state and a circumferential surface unit rising from an outer peripheral edge of the front surface portion and covering an outer peripheral surface of the housing rib from the outside in the locked state are provided, and plural dots protruding on the placing surface side are provided on at least part of a surface facing the placing surface in the locked state of the front surface portion. A pitch between the plural dots may be set to be equal to or higher than 0.5 mm and equal to or lower than 1.5 mm, and a height of the plural dots in the protruding direction on the placing surface side may be set to be equal to or higher than 0.01 mm and less than 0.05 mm.

Therefore, respective tips or respective tip portions of plural dots on the operation unit cover touch the portable device in the locked state of the operation unit cover.

The output device according to the embodiment of the present disclosure which houses a portable device in an internal space and which outputs at least audio or images outputted from the housed portable device to the outside includes a case body including a housing portion housing the portable device, a lid body to be locked to the case body, closing the housing portion in a locked state with respect to the case body and opening the housing portion in a lock release state with respect to the case body as well as a window portion is formed, and an operation unit cover made of transparent or semitransparent rubber materials and attached to the lid body in a state of closing the window portion, in which the housing portion includes a frame-shaped housing rib, the housing portion includes a housing recess surrounded by the housing rib and a bottom surface is a placing surface for the portable device, the operation unit cover is fitted onto the housing rib in the locked state to close the housing recess, the operation unit cover is provided with a front surface portion covering the housing recess in the locked state and a circumferential surface portion rising from an outer circumferential edge of the front surface portion and covering an outer peripheral surface of the housing rib in the locked state from the outside, and plural dots protruding on the placing surface side are provided at least part of a surface facing the placing surface in the locked state of the front surface portion. A pitch between the plural dots may be set to be equal to or higher than 0.5 mm and equal to or lower than 1.5 mm, and a height of the plural dots in the protruding direction on the placing surface side may be set to be equal to or higher than 0.01 mm and less than 0.05 mm.

As air bubbles or watermarks are not generated between the operation unit cover and the portable device, good visibility of the portable device can be secured and improvement in visibility and user-friendliness for the user can be realized.

Additionally, the sticking of the operation unit cover to the portable device can be prevented, therefore, the portable device is not lifted up while being stuck to the operation unit cover at the time of opening the lid body. Consequently, the falling of the portable device after the sticking and damage in the output device and the portable device can be prevented.

According to the embodiment of the present disclosure, the outer surface of the dots is formed to be a curved surface.

Therefore, the operation unit cover touches the portable device at point contact or in a state close to point contact, which can positively prevent generation of air bubbles or watermarks.

According to the embodiment of the present disclosure, the outer surface of the dots is formed to be a spherical surface.

Therefore, the operation unit cover touches the portable device at point contact or in a state close to point contact, which can positively prevent generation of air bubbles or watermarks as well as can perform molding of the operation unit cover easily.

According to the embodiment of the present disclosure, the front surface portion of the operation unit cover includes a holding surface portion facing the placing surface of the housing recess to hold the portable device and two inclined surface units respectively continuing from both ends of the holding surface portion, in which the distance to the placing surface is increased as drawing away from the holding surface portion, and the plural dots are provided on the holding surface portion.

As the dots are formed at minimum necessary positions, moldability of the operation unit cover can be improved without damaging the function of preventing generation of air bubbles or watermarks.

The operation unit cover according to the embodiment of the present disclosure is used for an output device which houses a portable device in an internal space, which outputs at least audio or images outputted from the housed portable device to the outside and which includes a case body having a housing portion including a housing recess surrounded by a frame-shaped housing rib and a bottom surface of which is a placing surface for the portable device to house the portable device, and a lid body to be locked to the case body, closing the housing portion in a locked state with respect to the case body and opening the housing portion in a lock release state with respect to the case body as well as a window portion is formed, in which the operation unit cover is made of transparent or semitransparent rubber materials and attached to the lid body in a state of closing the window portion and closes the housing recess by being fitted onto the housing rib in the locked state, a front surface portion covering the housing recess in the locked state and a circumferential surface unit rising from an outer peripheral edge of the front surface portion and covering an outer peripheral surface of the housing rib from the outside in the locked state are provided, and plural dots protruding on the placing surface side are provided on at least part of a surface facing the placing surface in the locked state of the front surface portion. A pitch between the plural dots may be set to be equal to or higher than 0.5 mm and equal to or lower than 1.5 mm, and a height of the plural dots in the protruding direction on the placing surface side may be set to be equal to or higher than 0.01 mm and less than 0.05 mm.

As air bubbles or watermarks are not generated between the operation unit cover and the portable device, good visibility of the portable device can be secured and improvement in visibility and user-friendliness for the user can be realized.

Additionally, the sticking of the operation unit cover to the portable device can be prevented, therefore, the portable device is not lifted up while being stuck to the operation unit cover at the time of opening the lid body. Consequently, the falling of the portable device after the sticking and damage in the output device and the portable device can be prevented.

### BRIEF DESCRIPTION OF THE DRAWINGS

FIG. 1 is a perspective view showing an output device;

FIG. 2 is a perspective view showing the output device in a state seen from the opposite direction to FIG. 1;

FIG. 3 is a perspective view showing the output device in a state in which a lid body is opened;

FIG. 4 is a perspective view showing the output device in a state in which the lid body is in an opened position;

FIG. 5 is a perspective view showing the output device in a state in which buckles are in a locked position;

FIG. 6 is a perspective view showing the output device in a state in which the buckles are in a lock release position;

FIG. 7 is a perspective view showing a case body in a state in which a nonslip sheet is separated;

FIG. 8 is an enlarged cross-sectional view in a state in which the buckle is in the lock release position;

FIG. 9 is an enlarged cross-sectional view in a state in which the buckle is in the locked position;

FIG. 10 is a perspective view showing the case body with a portable device;

FIG. 11 is a perspective view of a lid body;

FIG. 12 is an enlarged perspective view of an operation unit cover;

FIG. 13 is an enlarged cross-sectional view of the operation unit cover;

FIG. 14 is an enlarged back view showing a front surface portion of the operation unit cover;

FIG. 15 is an enlarged cross-sectional view showing the front surface portion of the operation unit cover;

FIG. 16 is an enlarged back view showing an example in which arrangement of dots in the front surface portion of the operation unit cover is different;

FIG. 17 is an enlarged back view showing an example in which dots of the front surface portion of the operation unit cover are arranged apart from one another;

FIG. 18 is an enlarged back view showing another example of the front surface portion of the operation unit cover;

FIG. 19 is an enlarged back view showing further another example of the front surface portion of the operation unit cover;

FIG. 20 is a cross-sectional view showing a state in which the lid body is pivoted to a closed position and the portable device is held by the operation unit cover;

FIG. 21 is an enlarged cross-sectional view showing a state in which the portable device is held by the operation unit cover seen from a direction orthogonal to the view shown in FIG. 20;

FIG. 22 is a perspective view showing a state in which the portable device connected to a connector is arranged in a housing recess;

FIG. 23 is an enlarged cross-sectional view showing a contact state of dots in the operation unit cover with respect to the portable device;

FIG. 24 is a cross-sectional view showing a state in which the lid body is pivoted from the opened position to the closed position and a first inclined surface of a locking protrusion touches a first inclined surface of a to-be-locked protrusion;

FIG. 25 is a cross-sectional view showing a state in which the lid body is further pivoted from the opened position to the closed position, a locking claw and a to-be-locked piece are elastically deformed and the locking claw climbs over the to-be-locked piece;

FIG. 26 is a cross-sectional view showing a state in which the locking claw and the to-be-locked piece are elastically returned and the lid body is locked with respect to the case body; and

FIG. 27 is a perspective view showing a state in which an operation unit of the portable device is operated from the outside of the operation unit cover.

### DETAILED DESCRIPTION

Hereafter, the best mode for carrying out the present disclosure will be explained with reference to the attached drawings.

An output device according to an embodiment of the present disclosure is, for example, a device outputting audio and images outputted from a portable device housed in an internal space to the outside, which includes a case body and a lid body connected to the case body so as to pivot about a hinge portion.

In the following explanation, directions are shown in a normal use state of the output device for convenience of explanation. The side where the case body is positioned is assumed to be the back and the side where the lid body is positioned is assumed to be the front in a state in which the portable device is housed in the internal space. Directions are also shown on the assumption that the hinge portion is positioned on a lower side and speaker units are positioned right and left.

The directions of up, down, front, back, left and right which will be described below are shown for convenience of explanation, and the present technology is not exclusively applied to these directions.

### <Structure of an Output Device>

An output device 1 has a structure in which a case body 2 and a lid body 3 are connected through a hinge portion 4 provided at a lower end portion, and the lid body 3 can pivot with respect to the case body 2 about the hinge portion 4.

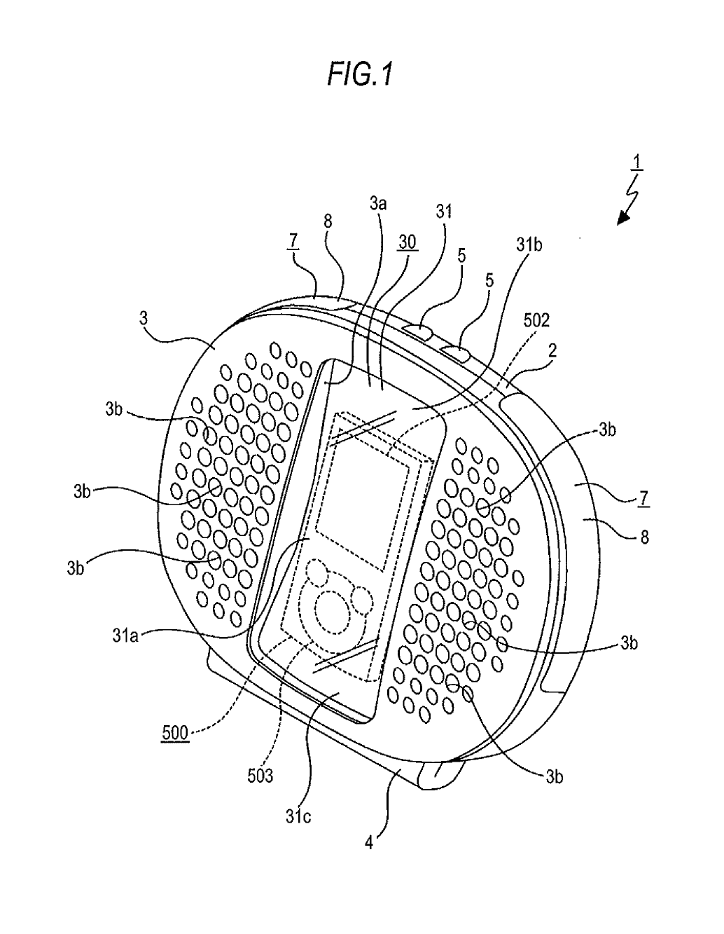

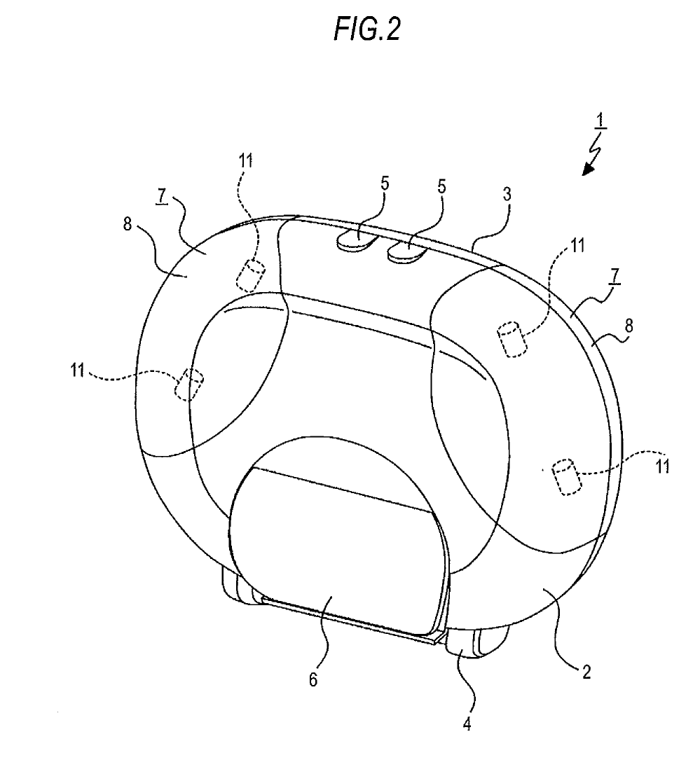

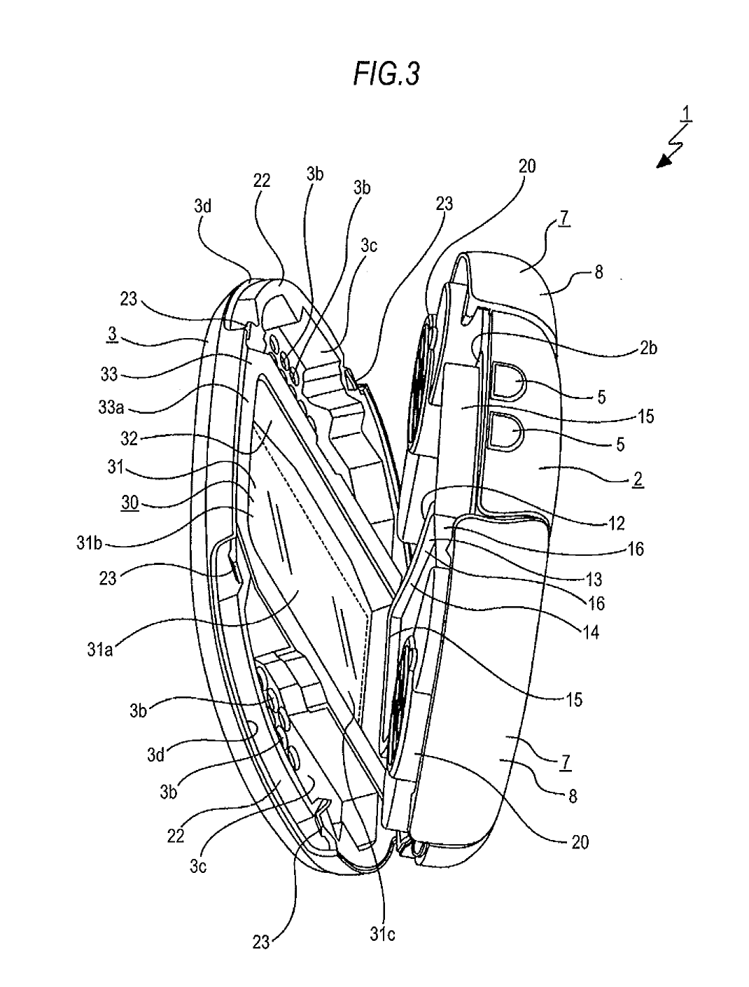

The case body 2 is formed to have, for example, an outer shape of rather oval in landscape orientation, and a portion ranging from an outer circumferential surface to an outer peripheral portion of a back surface is formed in a curved surface which is convex outward (refer to FIG. 2). On an upper surface of the case body, operation buttons 5, 5 are arranged right and left so as to be apart from each other (refer to FIG. 1 and FIG. 2). The operation buttons 5, 5 function as, for example, volume adjustment buttons for adjusting volume of audio outputted from a later-described portable device.

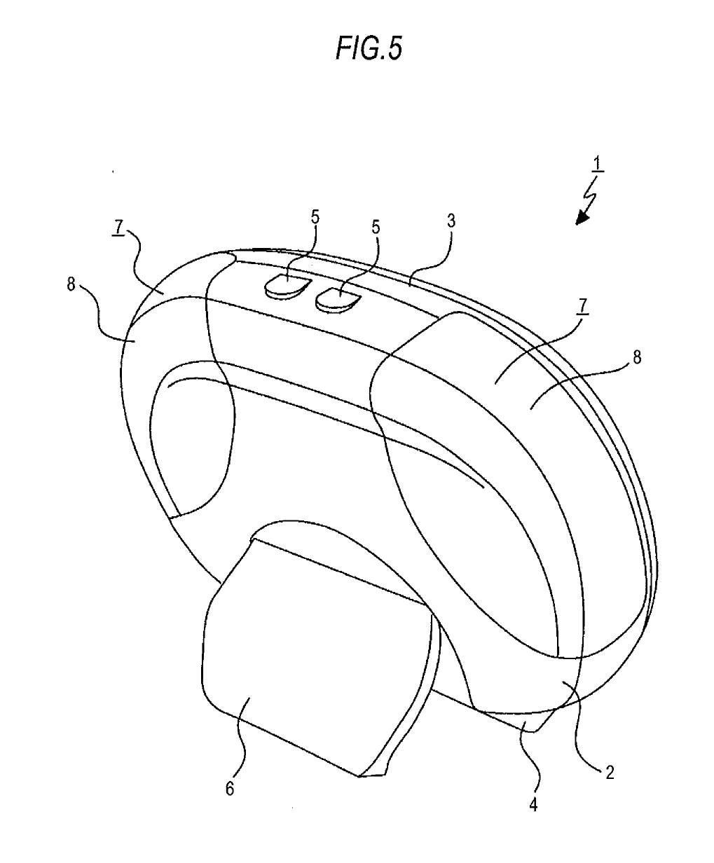

At a lower end portion of the case body 2 on the back side, a supporting stand 6 is pivotally connected (refer to FIG. 2). An upper end portion of the supporting stand 6 is connected to the case body 2. The output device 1 can be placed in a standing state by pivoting the supporting stand 6 to be pulled out from the case body 2 (refer to FIG. 5).

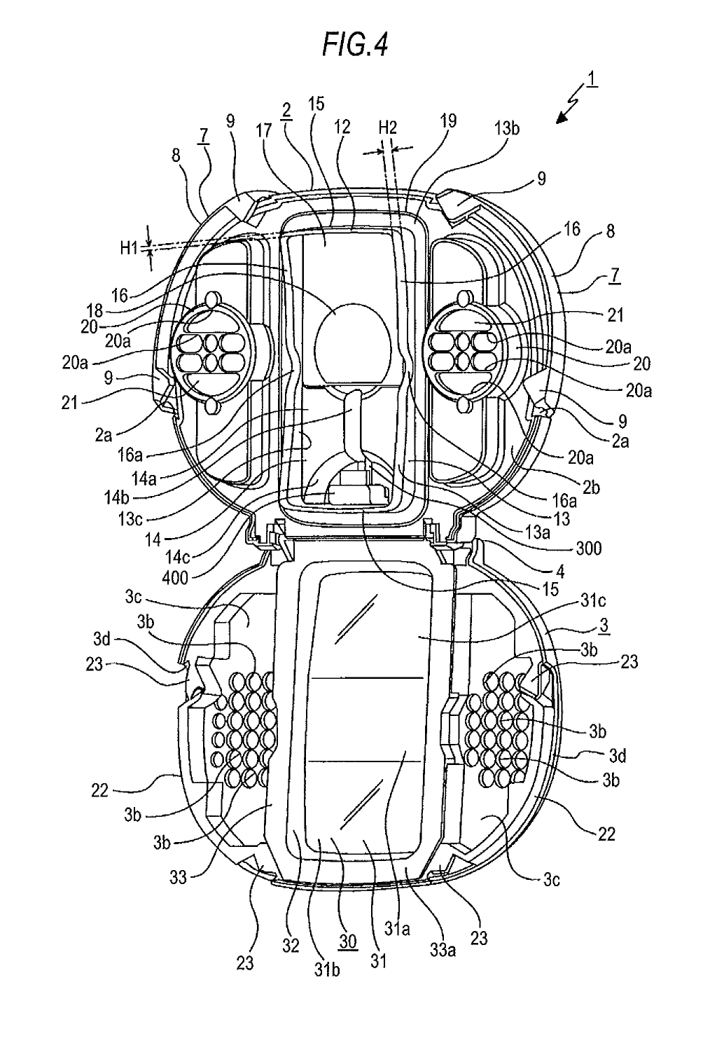

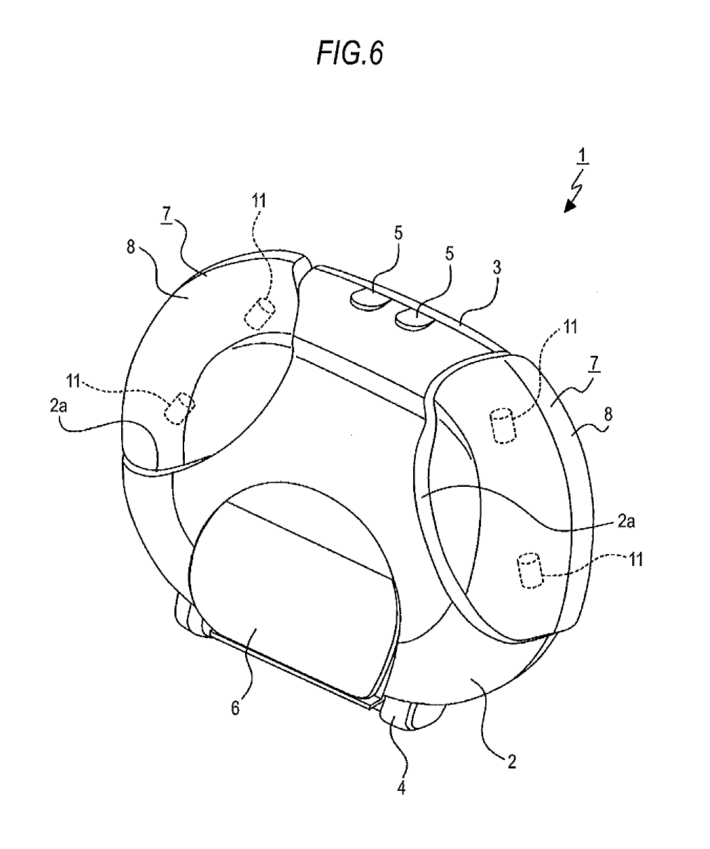

At right and left portions on both sides of the case body 2 on the upper side, shallow cutout portions for arrangement 2a, 2a are formed (refer to FIG. 6). Buckles 7, 7 are pivotally supported at right and left portions on both sides of the case body 2 respectively on the upper side. The buckles 7, 7 can pivot between a locked position (refer to FIG. 1 and FIG. 2) and a lock release position (refer to FIG. 4 and FIG. 6), and portions other than front end portions are housed in the cutout portions for arrangement 2a, 2a respectively in the locked position.

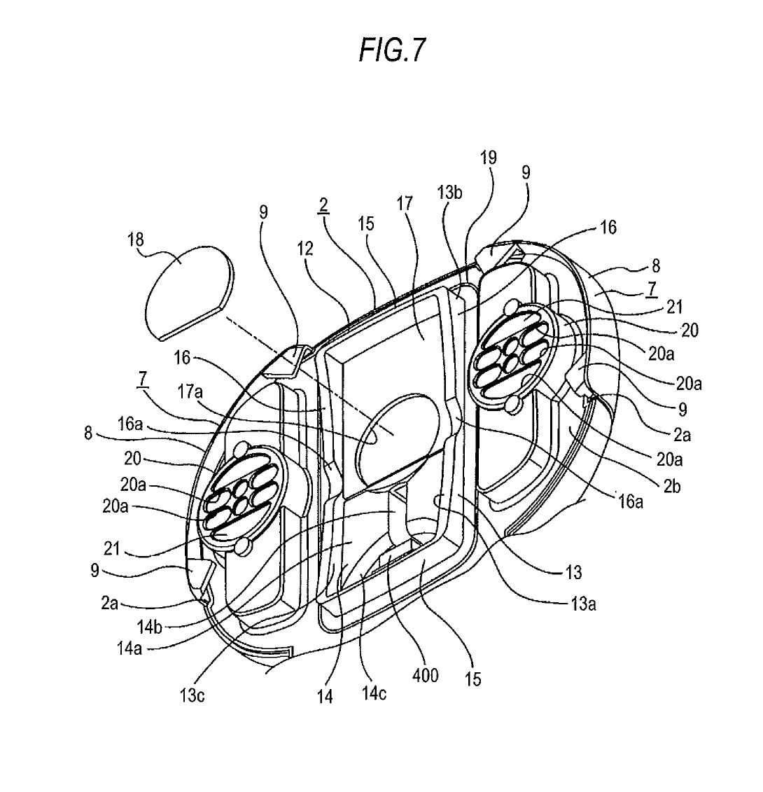

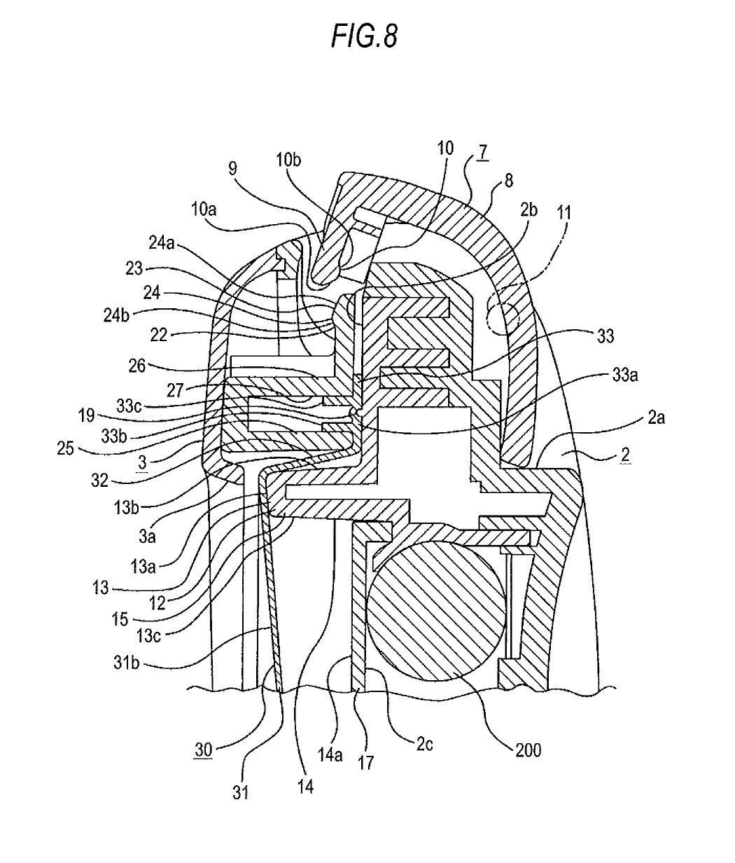

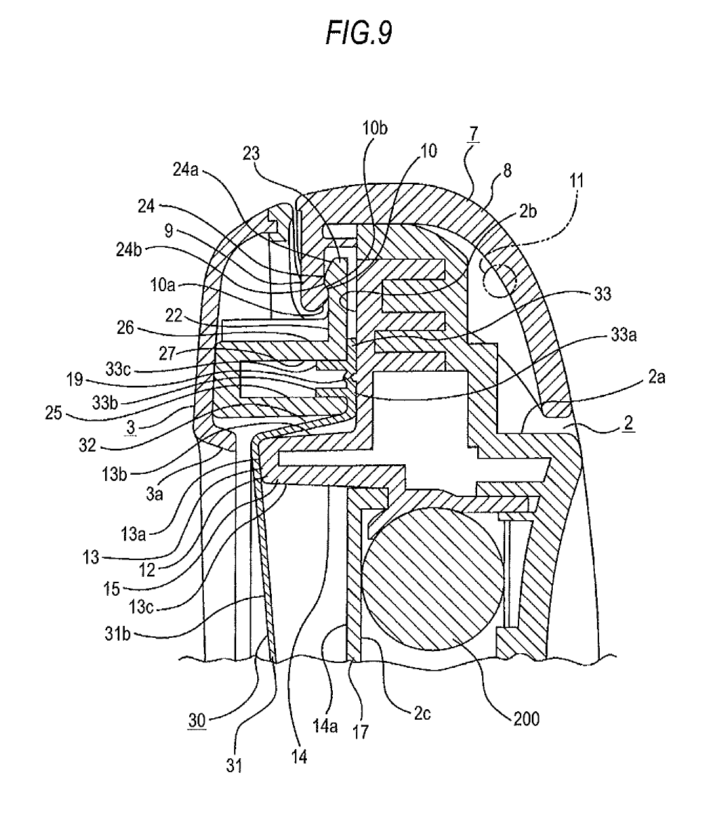

The buckle 7 includes a body 8, locking claws 9, 9 protruding inward from upper-and-lower both end portions (both end portions in a circumferential direction) in the front end portion of the body 8 and fulcrum shaft portions 11, 11 provided on the inner surface side of the body 8, which are integrally formed (refer to FIG. 4, FIG. 7, FIG. 8 and FIG. 9).

The locking claw 9 is formed in a triangular shape so as to be elastically deform with respect to the body 8, in which an locking protrusion 10 protruding backward is provided at a back surface of a tip portion (refer to FIG. 8 and FIG. 9). The locking protrusion 10 includes a first inclined surface 10a positioned at the tip portion side and inclining so as to be displaced backward as coming close to the body 8 and a second inclined surface 10b continuing from the first inclined surface 10a and inclining so as to be displaced forward as coming close to the body 8.

The buckles 7, 7 are positioned so that outer surfaces continue to an outer surface of the case body 2 (refer to FIG. 5 and FIG. 9) in the state of the locked position and are positioned so that front end portions are positioned on the outer side of the outer surface of the case body 2 in the state of the lock release position (refer to FIG. 6 and FIG. 8).

On a front surface 2b of the case body 2, a housing portion 12 is provided at the center in the right and left direction (refer to FIG. 4 and FIG. 7). A housing rib 13 formed to have an approximately rectangular-frame shape in portrait orientation is provided in the housing portion 12 and the inside of the housing rib 13 is formed as a housing recess 14.

The housing rib 13 includes first restriction walls 15, 15 positioned vertically apart from each other and extending right and left and second restriction walls 16, 16 positioned horizontally apart from each other and extending above and below. The protrusion amount (height) of the first restriction walls 15, 15 to the front direction from the front surface 2b of the case body 2 is constant, and the protrusion amount of the second restriction walls 16, 16 to the front direction from the front surface 2b of the case body 2 is increased from the center of the wall in the vertical direction toward upper and lower directions.

The housing rib 13 includes an edge surface 13a whose outer surface faces the front, an outer peripheral surface 13b continuing from an outer edge of the edge surface 13a and an inner peripheral surface 13c continuing from an inner edge of the edge surface 13a. At the center of the second restriction walls 16, 16 in the vertical direction, recesses for removal 16a, 16a are respectively formed. The recesses for removal 16a, 16 are communicated with the housing recess 14 and the edge surface portion 13a is formed in an approximately arc shape which is convex backward.

In the housing rib 13, a width of the edge surface 13a of the first restriction walls 15, 15 (a width H1 of an upper and lower edges) is formed to be smaller than a width of the edge surface 13a of the second restriction walls 16, 16 (a width H2 of right and left edges) as shown in FIG. 4.

The width H1 of the edge surface 13a of the first restriction walls 15, 15 is formed to be smaller as described above, thereby reducing the size of the housing rib 13 in the longitudinal direction which is the vertical direction to the minimum and miniaturizing the output device 1.

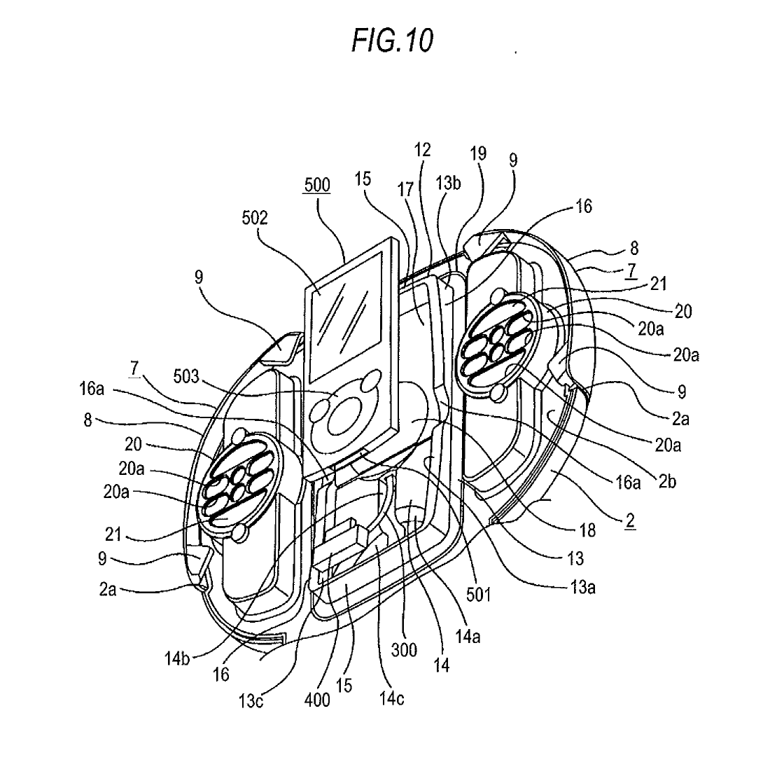

Concerning spaces between the inner peripheral surface 13c of the housing rib 13 and an outer peripheral surface of a portable device 500 (refer to FIG. 10), spaces between the portable device 500 and the second restriction walls 16, 16 in the right and left direction are liable to be smaller than spaces between the portable device 500 and the first restriction walls 15, 15 in the vertical direction when considering the size of the portable device 500. Therefore, it is more likely that contact occurs between the portable device 500 and the second restriction walls 16, 16 than between the device and the first restriction walls 15, 15. The width H2 of the edge surface 13a in the second restriction walls 16, 16 is formed to be larger, rigidity of the second restriction walls 16, 16 can be increased to thereby prevent damage occurring when the portable device 500 touches the walls.

The housing recess 14 is formed by the inner peripheral surface 13c of the housing rib 13 and a placing surface 14a facing the front as a bottom surface (refer to FIG. 4 and FIG. 7).

The case body 2 is provided with a battery mounting portion 2c (refer to FIG. 8 and FIG. 9), and the battery mounting portion 2c is closed by a battery lid 17 (refer to FIG. 7 to FIG. 9). The battery lid 17 is arranged at an approximately upper half portion of the housing recess 14, and a front surface of the battery lid 17 is formed as part of the placing surface 14a. The user can mount batteries 200, 200 . . . in the battery mounting portion 2c by opening the battery lid 17.

A shallow attachment recess 17a opening to the front is formed at the battery lid 17 (refer to FIG. 7). A nonslip sheet 18 made of rubber materials such as silicon rubber is attached to the attachment recess 17a of the battery lid 17. Arrangement of the nonslip sheet 18 to the housing recess 14 prevents slipping of the portable device 500 to be housed in the housing recess 14, which provides stability of a housing state of the portable device 500 in the housing recess 14.

The nonslip sheet 18 is detachable with respect to the attachment recess 17a, therefore, the nonslip sheet 18 can be washed by removing the nonslip sheet 18 from the attachment recess 17a.

In the housing recess 14, a cable arrangement groove 14b opening to the front and a connector arrangement groove 14c opening to the front are continuously formed in the vertical direction at a lower side of the battery lid 17.

A cable 300 is arranged in the cable arrangement groove 14b, and one end of the cable 300 is connected to a not-shown circuit substrate arranged inside the case body 2. The other end of the cable 300 is connected to a connector 400, which is arranged in the connector arrangement groove 14c.

The connector 400 and the cable 300 can be pulled out to the front from the connector arrangement groove 14c and the cable arrangement groove 14b respectively (refer to FIG. 10). The connector 400 and the cable 300 are pulled out to thereby connect the connector 400 to a connection terminal portion 501 of the portable device 500 easily.

On the outer periphery side of the housing rib 13 in the front surface 2b of the case body 2, a frame-shaped waterproof rib 19 is provided. An amount of protrusion of the waterproof rib 19 from the case body 2 is small, which is formed to have an approximately rectangular shape in portrait orientation.

In the front surface 2b of the case body 2, speaker arrangement portions 20, 20 are respectively provided so as to protrude forward at right and left of the housing portion 12. Output holes 20a, 20a, . . . , for outputting audio are formed in the speaker arrangement portions 20, 20. Respective units for outputting audio such as speakers 21, 21 and an amplifier circuit are respectively arranged inside the speaker arrangement portions 20, 20.

In the output device 1, the output holes 20a, 20a, are communicated with the inside of the case body 2, however, a not-shown waterproof structure for preventing infiltration of moisture to respective units arranged inside the case body 2 through the output holes 20a, 20a, . . . is provided inside the case body 2.

The lid body 3 is formed to have an outer shape of rather oval in landscape orientation like the case body 2, and a portion ranging from an outer circumferential surface to an outer peripheral portion at a front surface is formed in a curved surface which is convex outward (refer to FIG. 1).

A window portion 3a piercing in the front and back direction is formed at the center of the lid body 3 in the right and left direction, and the window portion 3a is formed to have approximately the same size and shape as the outer shape of the housing rib 13 of the case body 2.

Audio output holes 3b, 3b, . . . are formed in the lid body 3 at right and left of the window portion 3a. On a back surface side of the lid body 3, recesses 3c, 3c opening to the back are formed at right and left of the window portion 3a and the audio output holes 3b, 3b, . . . are communicated with the recesses 3c, 3c as shown in FIG. 4.

Shallow cutout portions 3d, 3d are formed at right-and-left portions of both sides of the lid body 3 on the upper side as shown in FIG. 4, FIG. 8 and FIG. 9, and the portions where the cutout portions 3d, 3d are formed in the lid body 3 are provided as engaging portions 22, 22 respectively.

At upper-and-lower both end portions of the engaging portion 22 (both end portions in the circumferential direction), to-be-locked pieces 23, 23 protruding outward are provided respectively. Tips of the to-be-locked pieces 23, 23 are positioned on an inner side of the outer circumferential surface of the lid body 3.

The to-be-locked piece 23 can be elastically deformed, and a to-be-locked protrusion 24 protruding forward is provided at a front surface of a tip portion (refer to FIG. 8 and FIG. 9). The to-be-locked protrusion 24 includes a first inclined surface 24a positioned on the tip side and inclining so as to be displaced forward as drawing away from the tip and a second inclined surface 24b continuing from the first inclined surface 24a and inclining so as to be displaced backward as drawing away from the tip.

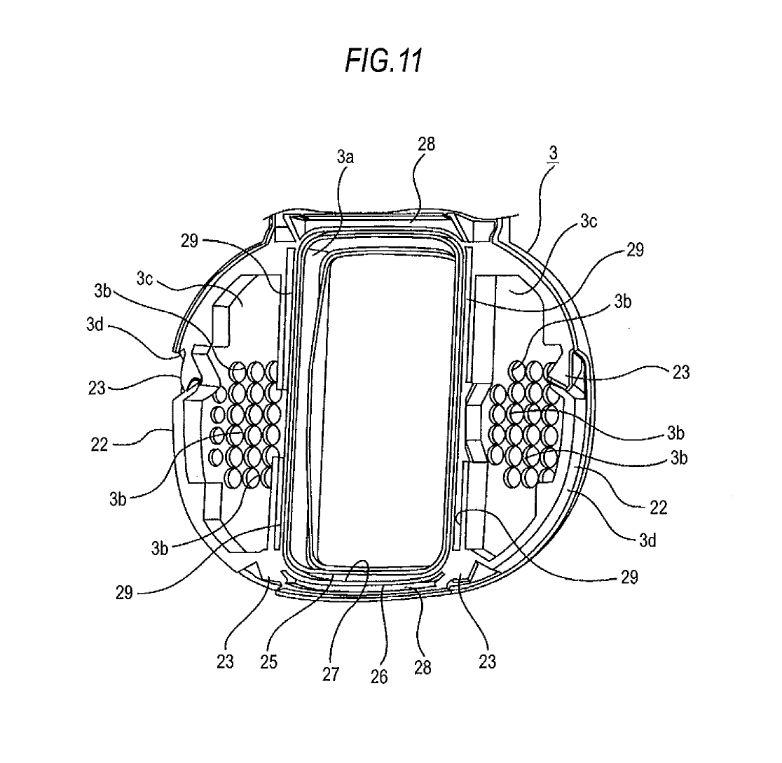

On the back side of the lid body 3, an inner wall portion 25 and an outer wall potion 26 having a frame shape are provided at the outer circumferential side of the window portion 3a, and the outer wall portion 26 is provided apart from the outer peripheral side of the inner wall portion 25 with a certain clearance as shown in FIG. 11. The clearance between the inner wall portion 25 and the outer wall portion 26 is formed as a holding groove 27 opens to the back.

On the back side of the lid body 3, first attachment grooves 28, 28 are formed above and below the outer wall portion 26. The first attachment grooves 28, 28 respectively extend in the right and left direction and open to the back. Additionally, second attachment grooves 29, 29, . . . are formed on the right and left sides of the outer wall portion 26 on the back side of the lid body 3, the second attachment grooves 29, 29, . . . respectively extend in the vertical direction and open to the back.

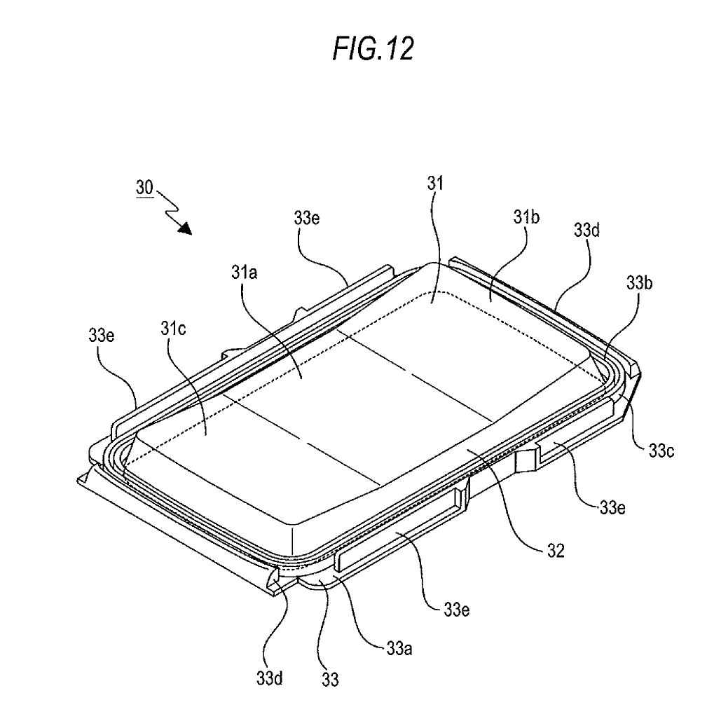

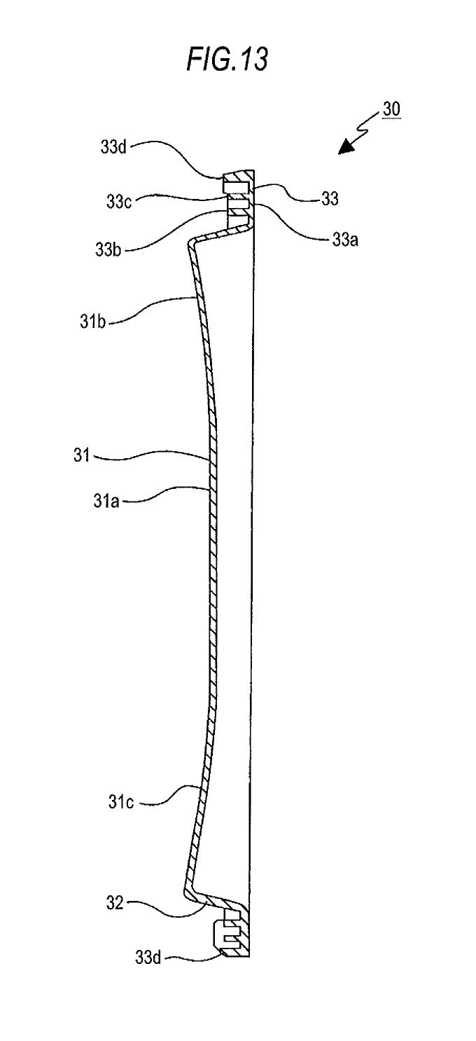

The lid body 3 is provided with an operation unit cover 30 (refer to FIG. 4). The operation unit cover 30 is made of transparent or semitransparent rubber materials such as silicon rubber. The operation unit cover 30 includes a front surface portion 31 formed to have an approximately rectangular shape in portrait orientation, a circumferential surface portion 32 rising from an outer circumferential edge of the front surface portion 31 to the backward direction and a flange portion 33 projecting outward from a back edge of the circumferential surface portion 32, which are integrally formed as shown in FIG. 12 and FIG. 13.

A portion of approximately one-third of the front surface portion 31 positioned at the center in the vertical direction is provided as a holding surface portion 31a having a flat-plate shape facing the front and the back, and portions positioned above and below the holding surface portion 31a are provided as inclined surface portions 31b, 31c gradually inclined so as to be displaced forward as drawing away from the holding surface portion 31a.

The circumferential surface portion 32 is inclined so as to be gradually displaced to the outside as coming backward, and an outer periphery of the back edge is slightly larger than an outer periphery of the front edge.

The flange portion 33 includes a base portion 33a facing front and back directions, a ring-shaped inner protruding ridge 33b and an outer protruding ridge 33c respectively protruding forward from the base portion 33a, first to-be-attached protrusions 33d, 33d and second to-be-attached protrusions 33e, 33e, . . . respectively protruding forward from the base portion 33a. The inner protruding ridge 33b is positioned with a certain clearance with respect to the circumferential surface portion 32 outside the circumferential surface portion 32 and the outer protruding ridge 33c is positioned with a certain clearance with respect to the inner protruding ridge 33b outside the inner protruding ridge 33b. The first to-be-attached protrusions 33d, 33d are positioned above and below the outer protruding ridge 33c so as to apart from the outer protruding ridge 33c and extend in the right and left direction. The second to-be-attached protrusions 33e, 33e, . . . are positioned at right and left sides of the outer protruding ridge 33c so as to apart from the outer protruding ridge 33c and extend upward and downward.

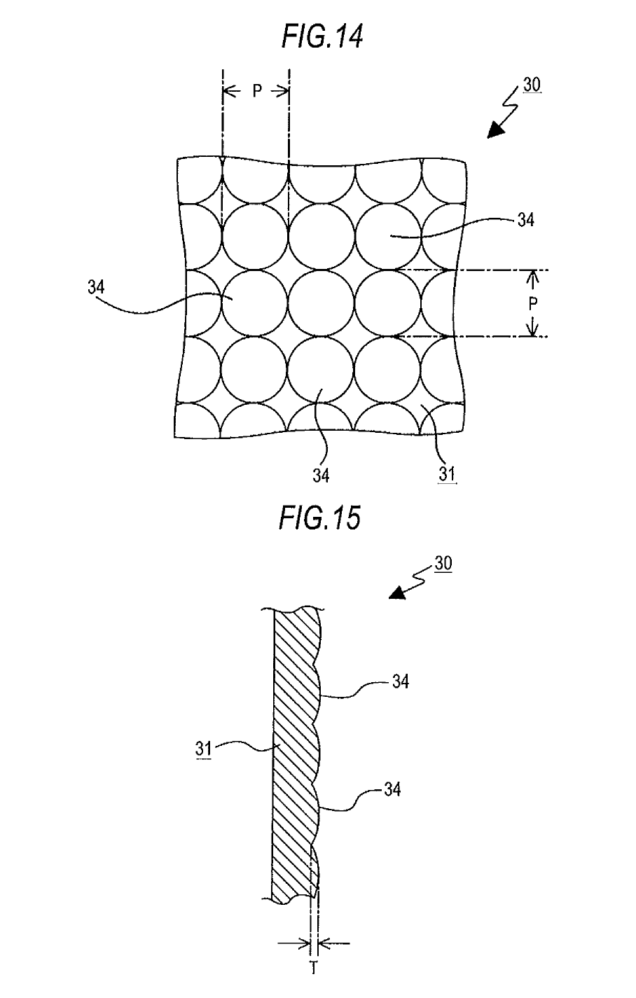

On a back surface of the front display portion 31, plural dots 34, 34, . . . are integrally formed (refer to FIG. 14 and FIG. 15). The back surface of the front surface portion 31 is a surface touching the portable device 500 housed in the housed portion 12 in a state in which the lid body 3 is locked with respect to the case body 2 as described later.

The dots 34, 34, . . . are, for example, regularly arranged and formed in a shape including part of an outer peripheral portion of a sphere, in which an outer surface is a spherical surface.

In the operation unit cover 30, a pitch P between the dots 34, 34, . . . (refer to FIG. 14) is, for example, set to be equal to or higher than 0.5 mm and equal to or lower than 1.5 mm, and a height T in a protruding direction of the dots 34 (refer to FIG. 15) is, for example, set to be equal to or higher than 0.01 mm and lower than 0.05 mm.

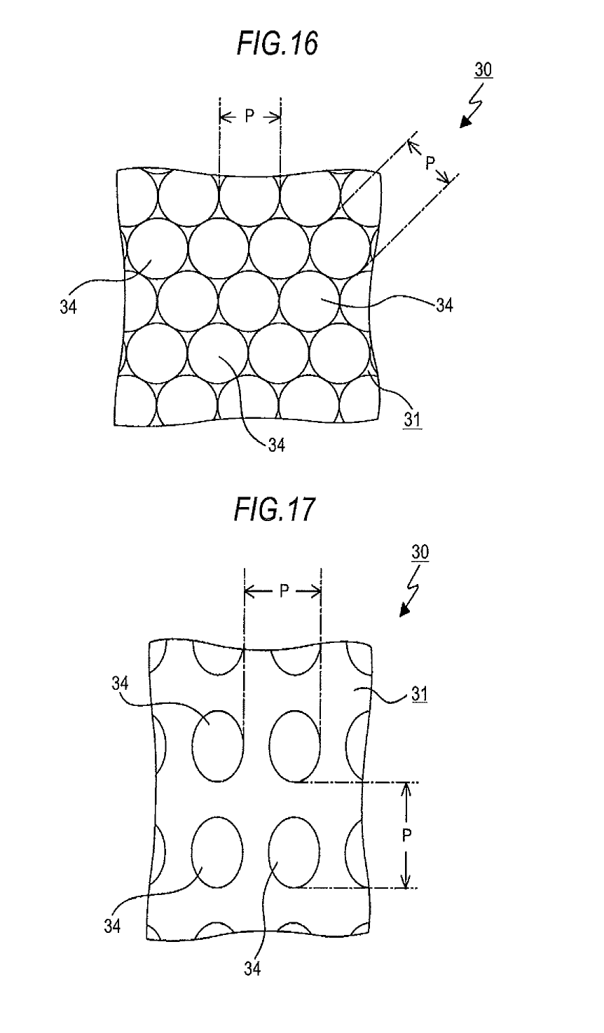

The regular arrangement of the dots 34, 34, . . . can be in a state, for example, in which the dots 34, 34, . . . are aligned adjacent to one another in vertical and horizontal lines (refer to FIG. 14), or can be arranged in a state in which they are shifted by radial width every other line or every other row (refer to FIG. 16). It is also preferable to apply an arrangement state in which the dots 34, 34, . . . are apart from one another with a given gap (refer to FIG. 17).

The example in which the dots 34, 34, . . . are formed in the shape including part of the outer peripheral portion of the sphere is shown as the above, however, the shape of the dots is not limited to this. The dots provided on the front surface portion 31 can be formed to have an optional shape as long as the dots touch the portable device 500 at point contact or in a state close to point contact when the front surface portion 31 makes contact with the portable device 500 in the state in which the portable device 500 is housed in the housing portion 12.

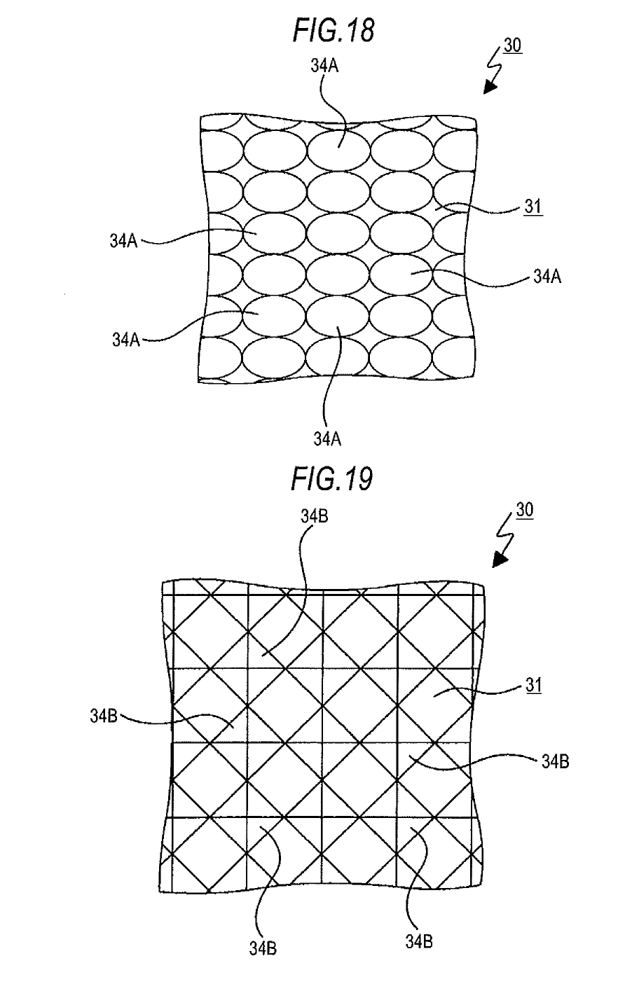

For example, it is also preferable to apply oval-shaped dots 34A, 34A, . . . in which the outer surface is formed to be a curved surface as shown in FIG. 18 or pyramid-shaped dots 34B, 34B, . . . as shown in FIG. 19.

It is not always necessary that the dots 34, 34, . . . , the dots 34A, 34A, . . . and the dots 34B, 34B, . . . are formed on the whole back surface of the front surface portion 31 and it is sufficient that they are formed on at least the holding surface portion 31a in the back surface of the front surface portion 31.

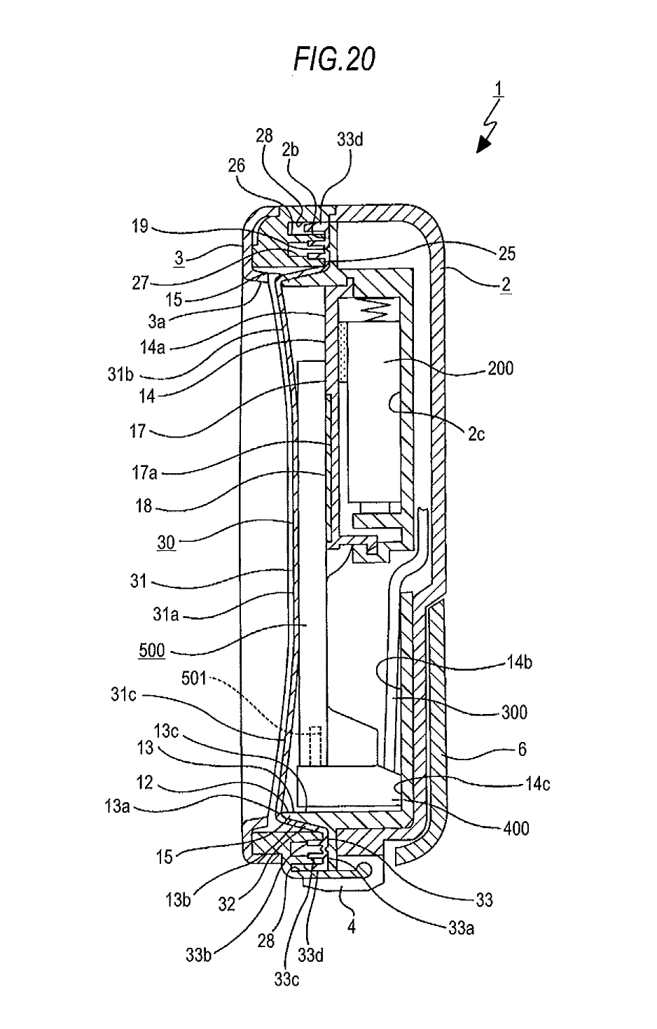

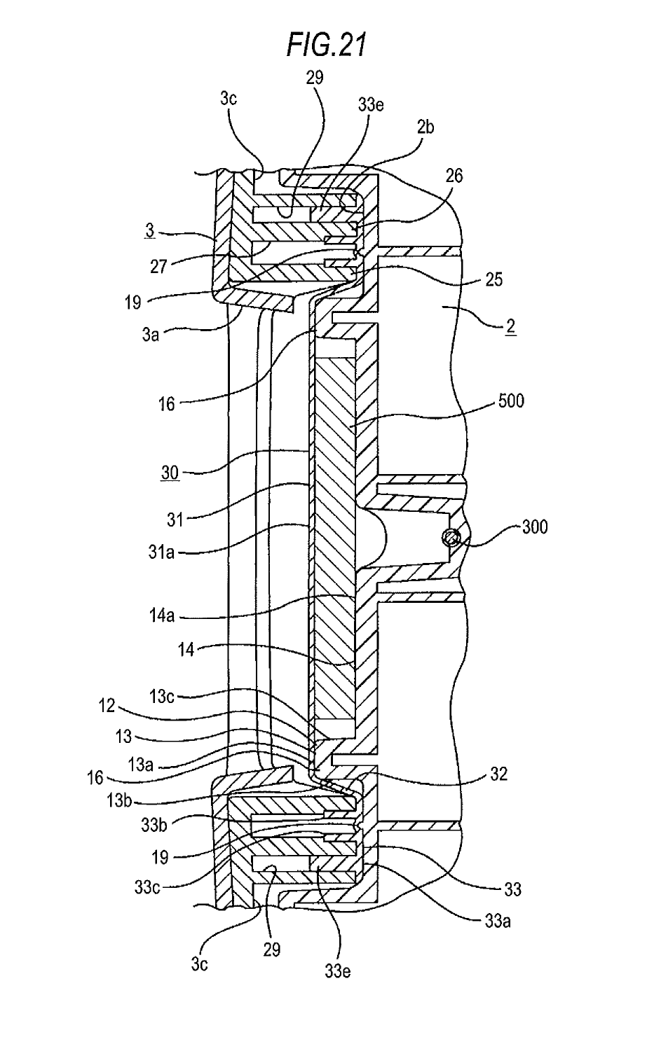

The front surface portion 31 and the circumferential surface portion 32 are inserted to the operation unit cover 30 from the back surface side of the window portion 3a (refer to FIG. 20 and FIG. 21). The operation unit cover 30 is attached to the lid body 3 by fitting the inner protruding ridge 33b and the outer protruding ridge 33c to the holding groove 27, fitting the first to-be-attached protrusions 33d, 33d to the first attachment grooves 28, 28 respectively and fitting the second to-be-attached protrusions 33e, 33e, . . . to second attachment grooves 29, 29, . . . respectively.

### <Open/Close Operation of the Lid Body>

Hereinafter, open/close operation of the lid body 3 will be explained.

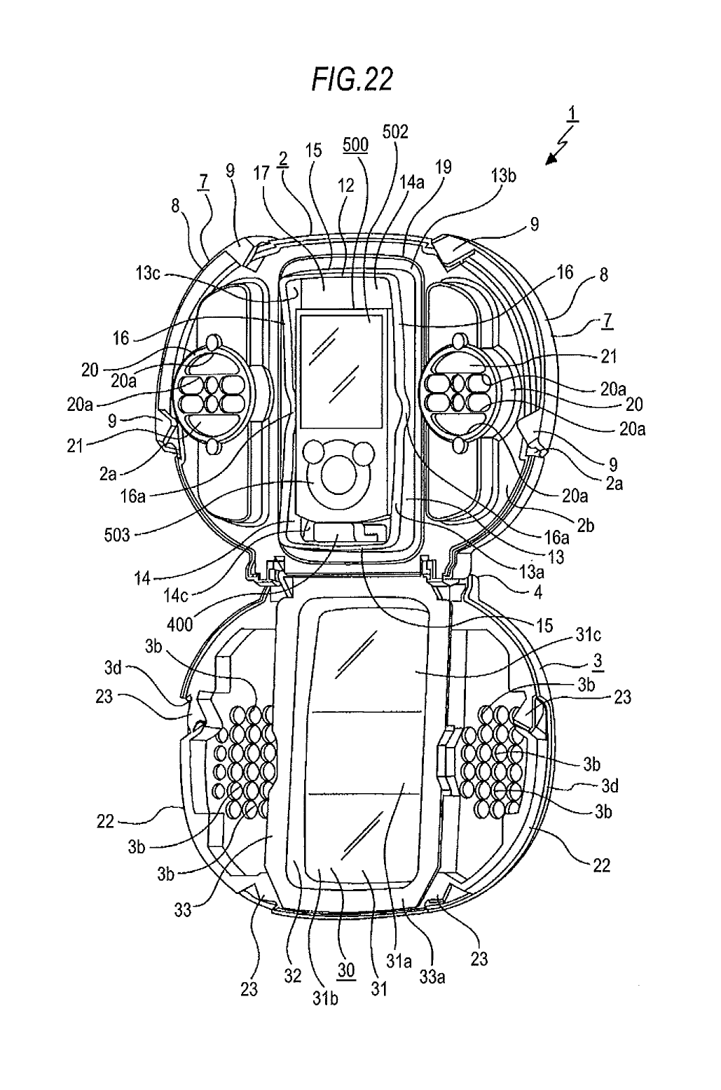

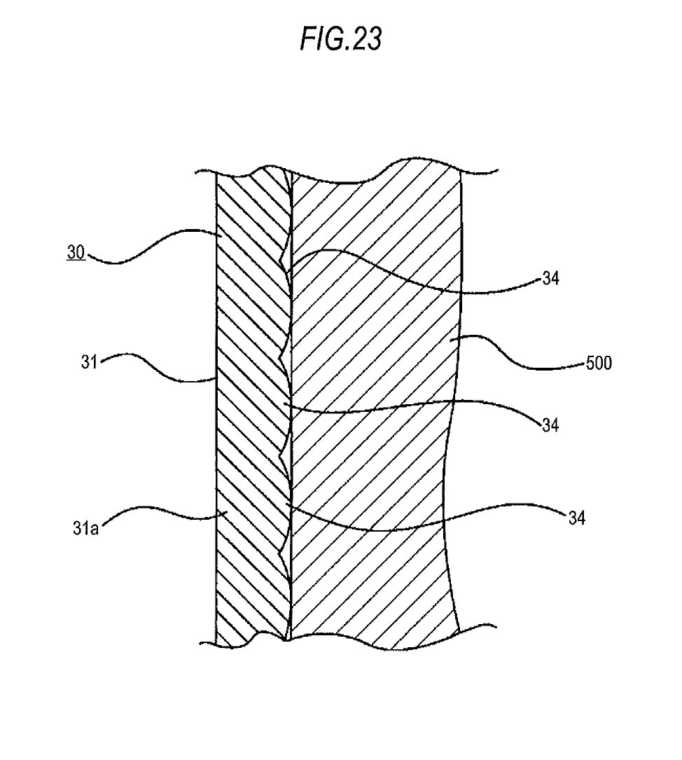

When the lid body 3 is an opened state, the portable device 500 is inserted in the housing recess 14 of the housing portion 12 and arranged there (refer to FIG. 22). At the time of arranging the portable device 500 in the housing recess 14, the connector 400 is connected to the connection terminal portion 501. At this time, the connector 400 and the cable 300 can be pulled forward from the connector arrangement groove 14c and the cable arrangement groove 14b respectively as described above, therefore, the connector 400 can be connected to the connection terminal portion 501 easily.

The portable device 500 arranged in the housing recess 14 is placed on the placing surface 14a in a state in which a display surface 502 on which images and characters are displayed and an operation unit 503 for performing given operation face the front. In the state in which the portable device 500 is placed on the placing surface 14a, slipping of the portable device 500 is prevented by the nonslip sheet 18 attached to the battery rid 17, which allows the arrangement state of the portable device 500 to be stable.

In the opened position where the lid body 3 is opened, the buckles 7, 7 supported on the case body 2 are pivoted to the lock release position.

When the lid body 3 is pivoted about the hinge portion 4 to a closed position, the operation unit cover 30 is fitted onto the housing rib 13 of the case body 2 (refer to FIG. 20 and FIG. 21), and the housing recess 14 and the portable device 500 arranged in the housing recess 14 are closed by the operation unit cover 30.

In the state in which the operation unit cover is fitted onto the housing rib 13, the outer periphery of the front surface portion 31 is positioned so as to abut on or close to the edge surface 13a of the housing rib 13 and the circumferential surface portion 32 is positioned so as to abut on or close to the outer peripheral surface 13b.

The flange portion 33 of the operation unit cover 30 is in a state in which a back surface of the base portion 33a of the flange portion 33 is pressed on the front surface 2b of the case body 2. At this time, a portion between the inner protruding ridge 33b and the outer protruding ridge 33c of the base portion 33a of the flange portion 33 is pressed on the waterproof rib 19, which gives waterproof property of the housing recess 14. As the portion of the base portion 33a pressed on the waterproof rib 19 is liable to be elastically deformed between the inner protruding ridge 33b and the outer protruding ridge 33c, adhesion with respect to the waterproof rib 19 is good, therefore, the housing recess 14 and the portable device 500 arranged in the housing recess 14 can be waterproofed.

In the state in which the lid body 3 is pivoted to be in the closed position, the portable device 500 is held by portions other than part of the front surface portion 31 of the operation unit cover 30, for example, by the holding surface portion 31a or by the holding surface portion 31a and part of the inclined surface portions 31b, 31c (refer to FIG. 20). Therefore, the movement of the portable device 500 in the housing recess 14 is restricted and the stable housing state of the portable device 500 in the housing recess 14 can be secured.

In the above state, the portable device 500 is held by the holding surface portion 31a of the operation unit cover or by the holding surface portion 31a and part of the inclined surface portions 31b, 31c, therefore, all or part of the inclined surface portions 31b, 31c does not touch the portable device 500.

In the output device 1, the size of the housing portion 12 is prescribed to a fixed size by the housing rib 13 and the operation unit cover 30 is formed in a box shape having the front surface portion 31 and the circumferential surface portion 32 so as to correspond to the size and shape of the housing rib 13. Accordingly, the housing portion 12 and the window portion 3a of the lid body 3 are formed to have the minimum size, which realizes miniaturization of the output device 1.

As the housing rib 13 protruding forward from the front surface 2b is provided in the housing unit 12, for example, infiltration of moisture to the housing recess 14 occurring when moisture is attached to the front surface 2b can be prevented, which improves waterproof property.

Furthermore, when the position of the portable device 500 housed in the housing recess 14 is moved due to the shock, vibration and so on, the moved portable device 500 abuts against the housing rib 13 and the movement is restricted. Therefore, the state in which the portable device 500 is held on the front surface portion 31 of the operation unit cover 30 can be maintained even when the shock, vibration and so on occur.

As described above, the dots 34, 34, . . . are formed on the front surface portion 31 of the operation unit cover 30, therefore, the dots 34, 34, . . . touch the portable device 500 at point contact or in a state close to point contact in the state in which the portable device 500 is held by the front surface portion 31 of the operation unit cover 30 (refer to FIG. 23).

Accordingly, in the state in which the portable device 500 is held by the operation unit cover 30, generation of air bubbles due to entering of air into part of the contact surface of the operation unit cover 30 with respect to the portable device 500 as well as generation of watermarks due to sticking of the operation unit cover 30 to the display surface 502 of the portable device 500 can be prevented. As air bubbles or watermarks are not generated between the operation unit cover 30 and the portable device 500 as described above, good visibility of the display surface 502 and the operation unit 503 can be secured and improvement in visibility and user-friendliness for the user can be realized.

Additionally, the sticking of the operation unit cover 30 to the portable device 500 can be prevented, therefore, the portable device 500 is not lifted up while being stuck to the operation unit cover 30 at the time of opening the lid body 3. Consequently, smooth open/close operation of the lid body 3 can be secured as well as the falling of the portable device 500 after the sticking and damage in the output device 1 and the portable device 500 can be prevented.

Moreover, the outer surface of the dots 34, 34, . . . is formed to be the curved surface in the operation unit cover 30, therefore, the operation unit cover 30 touches the portable device 500 at point contact or in a state close to point contact, which can positively prevent generation of air bubbles or watermarks. Particularly, the generation of air bubbles or watermarks can be positively prevented as well as molding of the operation unit cover 30 can be easily performed by forming the outer surface of the dots 34, 34, . . . in the spherical surface shape.

Furthermore, the dots 34, 34, . . . are formed at minimum necessary positions as they are formed only on the holding surface portion 31a of the operation unit cover 30, which improves moldability of the operation unit cover 30 without damaging the function of preventing generation of air bubbles or watermarks.

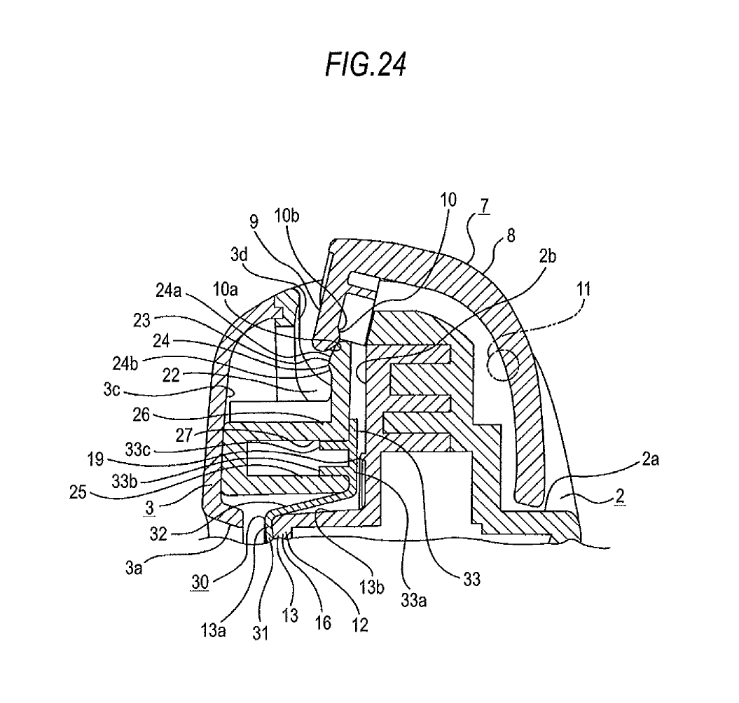

When the buckles 7, 7 are pivoted from the lock release position to the locked position in the state in which the lid body 3 is pivoted to the closed position, the lid body 3 is locked with respect to the case body 2 in the closed position as explained below (refer to FIG. 24 to FIG. 26).

As the buckle 7 is pivoted from the lock release position toward the locked position, the first inclined surface 10a of the locking protrusion 10 provided at the locking claw 9 of the buckle 7 touches the first inclined surface 24a of the to-be-locked protrusion 24 provided at the to-be-locked piece 23 of the lid body 3 (refer to FIG. 24).

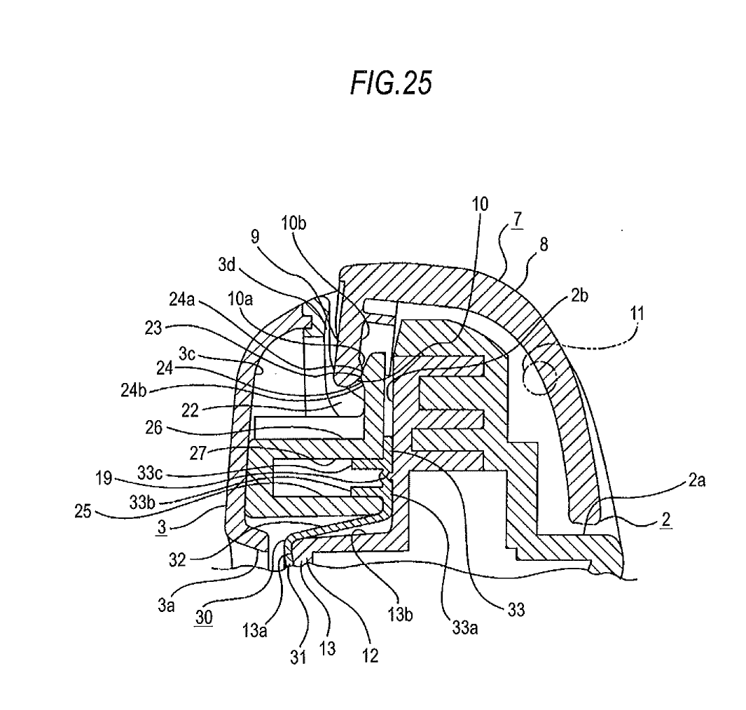

When the buckle 7 is further pivoted toward the locked position, the first inclined surface 10a of the locking protrusion 10 makes sliding contact with the first inclined surface 24a of the to-be-locked protrusion 24, and the locking claw 9 and the to-be-locked piece 23 are elastically deformed, as a result, the locking claw 9 climbs over the to-be-locked piece 23 (refer to FIG. 25).

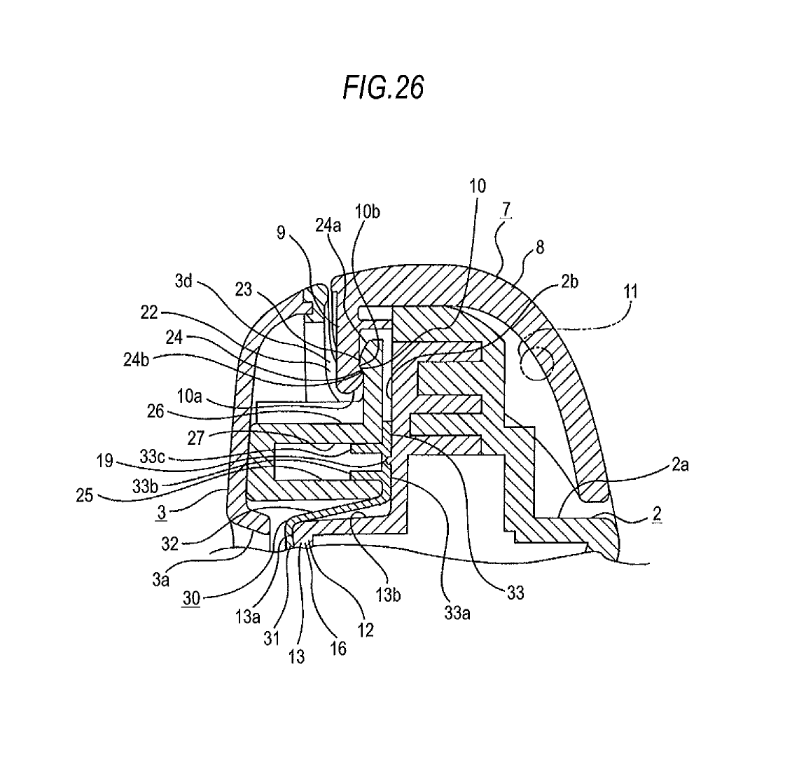

When the buckle 7 is further pivoted toward the locked position, the second inclined surface 10b of the locking protrusion 10 makes sliding contact with the second inclined surface 24b of the to-be-locked protrusion 24, and the locking claw 9 and the to-be-locked piece 23 are elastically returned, as a result, the second inclined surface 10b of the locking protrusion 10 is engaged with the second inclined surface 24b of the to-be-locked protrusion 24 (refer to FIG. 26). The second inclined surface 10b of the locking protrusion 10 is engaged with the second inclined surface 24b of the to-be-locked protrusion 24, thereby allowing the buckle 7 to be in the locked position and allowing the lid body 3 to be locked with respect to the case body 2.

As described above, when the lid body 3 is locked with respect to the case body 2, the flange portion 33 of the operation unit cover 30 is pressed onto the portion around the housing rib 13 on the front surface 2b of the case body 2, which secures good waterproof property with respect to the housing portion 12.

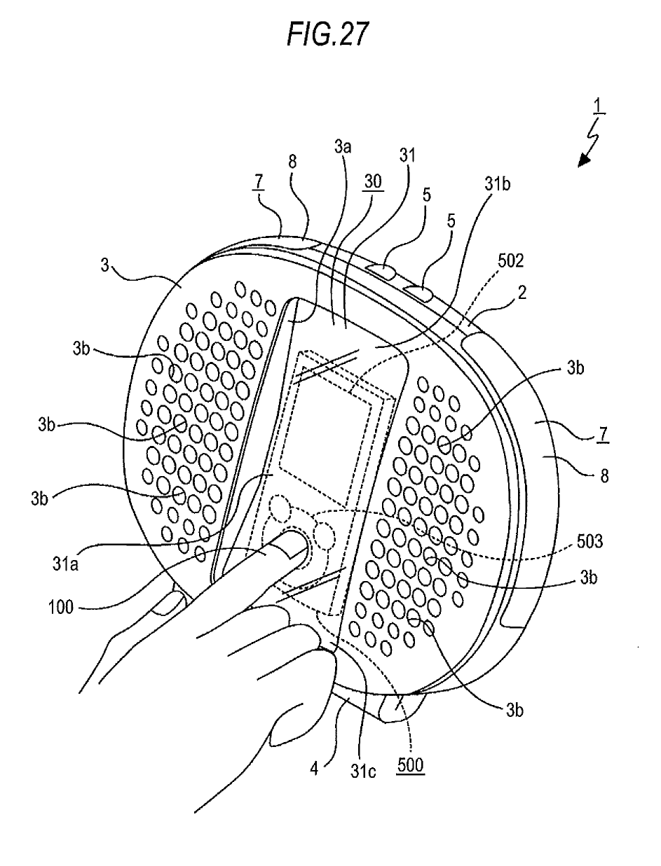

In the state in which the lid body 3 is locked with respect to the case body 2, operation is performed by a finger 100 with respect to the operation unit 503 of the portable device 500 which is pressed onto the placing surface 14a of the housing recess 14 by the operation unit cover 30 (refer to FIG. 27). When the operation is performed with respect to the operation unit 503 of the portable device 500, for example, audio output from the portable device 500 is transmitted to the speakers 21, 21 through the connector 400, as a result, audio is outputted from the speakers 21, 21. The audio outputted from the speakers 21, 21 is outputted to the outside through the output holes 20a, 20a, . . . formed in the speaker arrangement portions 20, 20 of the case body 2 and the audio output holes 3b, 3b, . . . formed in the lid body 3.

Additionally, images displayed (outputted) on the display surface 502 of the portable device 500 are transmitted through the front surface portion 31 of the operation unit cover 30 and outputted to the outside.

In the state in which the lid body 3 is locked with respect to the case body 2, the lock of the lid body 3 with respect to the case body 2 is released by pivoting the buckles 7, 7 from the locked position to the lock release position.

The pivoting operation from the locked position to the lock release position of the buckle 7 is a reverse operation to the pivoting operation from the lock release position to the locked position. That is, the release of the lock of the lid body 3 with respect to the case body 2 is performed in the manner in which the buckle 7 is pivoted from the locked position to the lock release position, the locking claw 9 and the to-be-locked piece 23 are elastically deformed and the locking claw 9 climbs over the to-be-locked piece 23, then, the buckle 7 is further pivoted toward the lock release position and the locking claw 9 and the to-be-locked piece 23 are elastically returned.

The lid body 3 is pivoted from the closed position to the opened position in the state in which the lock of the lid body 3 with respect to the case body 2 is released, thereby removing the portable device 500 from the housing recess 14.

The removal of the portable device 500 from the housing recess 14 can be easily performed by inserting two fingers into the housing recess 14 through the recesses for removal 16a, 16a formed in the second restriction walls 16, 16 of the housing rib 13 and holding the portable device 500 from right-and-left both sides.

The recesses for removal 16a, 16a are formed in the housing rib 13 as described above, therefore, the portable device 500 can be easily removed from the housing recess 14, which improves user-friendliness of the output device 1.

### <Others>

In the above description, the structure in which a pair of buckles 7, 7 is pivotally supported at the case body 2 and the engaging portions 22, 22 to be engaged with the buckles 7, 7 are provided at the lid body 3 has been shown, however, a structure in which a pair of buckles are pivotally supported at the at the lid body and engaging portions to be engaged with the buckles are provided at the case body can be also applied in an opposite manner.

Specific shapes and structures of respective units shown in the above embodiment are just examples in the embodiment for carrying out the present disclosure, and the technical scope of the present disclosure should not be interpreted in a limited manner.

The present disclosure contains subject matter related to that disclosed in Japanese Priority Patent Application JP 2010-189538 filed in the Japan Patent Office on Aug. 26, 2010, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An output device which houses a portable device in an internal space and which outputs at least audio or images outputted from the housed portable device to the outside, comprising:
a case body including a housing portion housing the portable device;
a lid body to be locked to the case body, closing the housing portion in a locked state with respect to the case body and opening the housing portion in a lock release state with respect to the case body as well as a window portion is formed; and
an operation unit cover made of transparent or semitransparent rubber materials and attached to the lid body in a state of closing the window portion,
wherein the housing portion includes a frame-shaped housing rib,
the housing portion includes a housing recess surrounded by the housing rib and a bottom surface is a placing surface for the portable device,
the operation unit cover is fitted onto the housing rib in the locked state to close the housing recess,
the operation unit cover is provided with a front surface portion covering the housing recess in the locked state and a circumferential surface portion rising from an outer circumferential edge of the front surface portion and covering an outer peripheral surface of the housing rib in the locked state from the outside, and
plural dots protruding on the placing surface side are provided at least part of a surface facing the placing surface in the locked state of the front surface portion.

2. The output device according to claim 1,
wherein a pitch between the plural dots is set to be equal to or higher than 0.5 mm and equal to or lower than 1.5 mm, and
a height of the plural dots in the protruding direction on the placing surface side is set to be equal to or higher than 0.01 mm and less than 0.05 mm.

3. The output device according to claim 1,
wherein an outer surface of the dots is formed to be a curved surface.

4. The output device according to claim 3,
wherein an outer surface of the dots is formed to be a spherical surface.

5. The output device according to claim 1,
wherein the front surface portion of the operation unit cover includes a holding surface portion facing the placing surface of the housing recess to hold the portable device and two inclined surface units respectively continuing from both ends of the holding surface portion, in which the distance to the placing surface is increased as drawing away from the holding surface portion, and
the plural dots are provided on the holding surface portion.

6. An operation unit cover used for an output device which houses a portable device in an internal space, which outputs at least audio or images outputted from the housed portable device to the outside and which includes a case body having a housing portion including a housing recess surrounded by a frame-shaped housing rib and a bottom surface of which is a placing surface for the portable device to house the portable device, and a lid body to be locked to the case body, closing the housing portion in a locked state with respect to the case body and opening the housing portion in a lock release state with respect to the case body as well as a window portion is formed,
wherein the operation unit cover is made of transparent or semitransparent rubber materials and attached to the lid body in a state of closing the window portion and closes the housing recess by being fitted onto the housing rib in the locked state,
a front surface portion covering the housing recess in the locked state and a circumferential surface unit rising from an outer peripheral edge of the front surface portion and covering an outer peripheral surface of the housing rib from the outside in the locked state are provided, and
plural dots protruding on the placing surface side are provided on at least part of a surface facing the placing surface in the locked state of the front surface portion.

7. The output unit cover according to claim 6,
wherein a pitch between the plural dots is set to be equal to or higher than 0.5 mm and equal to or lower than 1.5 mm, and
a height of the plural dots in the protruding direction on the placing surface side is set to be equal to or higher than 0.01 mm and less than 0.05 mm.
